(19) United States
(12) Patent Application Publication
(10) Pub. No.: US 2023/0328933 A1
(43) Pub. Date: Oct. 12, 2023

(54) INTEGRATED HEAT SPREADER

(71) Applicant: Honeywell International Inc., Charlotte, NC (US)

(72) Inventors: Prashant Hegde, Sriracha (TH); Nishanth Selvaraj, Sriracha (TH); Baskaran Selvan, Sriracha (TH)

(21) Appl. No.: 18/123,139

(22) Filed: Mar. 17, 2023

Related U.S. Application Data
(60) Provisional application No. 63/329,620, filed on Apr. 11, 2022.

(51) Int. Cl. H05K 7/20; B21D 53/04

(52) U.S. Cl. CPC H05K 7/20509; B21D 53/04

(57) ABSTRACT

A heat spreader includes a longitudinal axis, a top surface opposite a bottom surface, a plurality domes formed within and extending from the bottom surface, wherein each dome of the plurality of domes is defined by a radius and a depth, and wherein the plurality of domes are longitudinally aligned with one another along the longitudinal axis.

### CROSS-REFERENCE TO RELATED APPLICATION

This application claims priority to U.S. Provisional Application No. 63/329,620, filed Apr. 11, 2022, which is herein incorporated by reference in its entirety.

### TECHNICAL FIELD

The present disclosure relates generally to an integrated heat spreader and methods of forming an integrated heat spreader.

### BACKGROUND

Heat spreaders are often used in computer chip packages to draw heat from a chip, semiconductor die, and/or processor and transfer the heat to a heat sink to be dissipated. FIG. 1 illustrates a system established in the art and incorporates the use of heat spreaders. Specifically, a substrate 10 is shown positioned below a chip 12, also referred to as a die, that may be positioned adjacent and below a thermal interface material sheet 14. In some uses, the thermal interface material sheet 14 is composed of various types of polymers, such as silicone, for example. The chip 12 and thermal interface material sheet 14 may be arranged adjacent, and in some embodiments, within a recessed portion of, a heat spreader 20. The heat spreader 20 is arranged adjacent a second layer of the thermal interface material 14. Adjacent the second layer of the thermal interface material 14, the system may include a heat sink 18.

As a result of the above described configuration, during operation of the chip 12, heat generated by the chip 12 is discharged to the heat sink 18 via the heat spreader 20. The heat spreader 20 is able to disperse and spread the heat across the heat spreader 20, facilitating efficient heat transfer to the heat sink 18. In this way, the heat generated by the chip 12 does not cause localized damage to the components in the system. The heat that is dispersed by the heat spreader 20 may then be transferred to the heat sink 18 to be dissipated.

As previously described, in some instances, the heat spreader 20 may have a recess or cavity configured for receiving the chip 12. FIGS. 2A and 2B illustrate an additional embodiments of the heat spreader 20. As illustrated, the heat spreader 20 includes a top side 22 and a bottom side 24, the bottom side 24 having a cavity 26 extending within the bottom side 24. In operation, the chip 12 (FIG. 1) may be arranged within the cavity 26. In these embodiments, it may be desired to have a recess and/or cavity of a shape and size that is optimized to engage with the chip 12 being incorporated into the system.

In manufacture, the heat spreaders 20 may be formed in large volumes by cutting a blank from the sheet or strip of bulk material and by using a combination of stamping processes to impart the desired shape and features to the blank to ultimately produce the desired heat spreader. When the heat spreader 20 includes the cavity 26, the cavity 26 may be formed from punching the material from the blank into a shape and geometry configured for receiving the processor or die in operation. During this process of punching the heat spreader 20 to form the desired shape, the punching force causes cold flow of the material from areas of high pressure into areas of lower pressure. As such, a stamping system can be designed with desired sizes and/or shapes to create the target shape of the cavity 26.

### SUMMARY

The present disclosure provides a heat spreader having a longitudinal axis and including a top surface opposite a bottom surface, a plurality domes formed within and extending from the bottom surface, wherein each dome of the plurality of domes is defined by a radius and a depth, and wherein the plurality of domes are longitudinally aligned with one another along the longitudinal axis.

In one form thereof, the present disclosure provides a heat spreader including a top surface opposite a bottom surface, a first cavity within and extending upwardly from the bottom surface, the first cavity defined by a lateral radius and a depth, a second cavity within and extending upwardly from the bottom surface and positioned adjacent the first cavity, the second cavity defined by a lateral radius and a depth, and a third cavity within and extending upwardly from the bottom surface and positioned adjacent the second cavity, the third cavity defined by a lateral radius and a depth. The heat spreader further includes wherein the first, second and third cavities are defined by a generally domed profile.

In another form thereof, the present disclosure provides a method of forming a heat spreader including stamping a central surface of a sheet of material with a die and a press of a stamping system to transfer material outward form a central surface, constrained the material of atop surface of the sheet of material in a substantially constant geometry, and during the step of constraining, stamping a plurality of domes into a bottom surface of the sheet of material with a second die and a second press of a second stamping system to create a heat spreader.

### BRIEF DESCRIPTION OF FIGURES

The above mentioned and other features of this invention, and the manner of attaining them, will become more apparent and the invention itself will be better understood by reference to the following description of embodiments of the invention taken in conjunction with the accompanying drawings, where:

FIG. 1 illustrates a schematic of an example use for a heat spreader;

FIG. 2A illustrates a heat spreader as is known generally in the art;

FIG. 2B illustrates a heat spreader as is known generally in the art;

FIG. 3 illustrates a schematic example press machine that may be used for manufacturing a heat spreader, in accordance with embodiments of the present disclosure;

FIG. 4A illustrates a bottom view of an example heat spreader, in accordance with embodiments of the present disclosure;

FIG. 4B illustrates a cross sectional view of the heat spreader of FIG. 4A, taken along the line 4B-4B;

FIG. 5A illustrates a bottom view of an example heat spreader, in accordance with embodiments of the present disclosure;

FIG. 5B illustrates a cross sectional view of the example heat spreader of FIG. 5A, taken along the line 5B-5B, in accordance with embodiments of the present disclosure;

FIG. 6A illustrates a cross sectional view of a work piece, in accordance with embodiments of the present disclosure;

FIG. 6B illustrates a cross sectional view of the work piece of FIG. 6A positioned within a stamping system;

FIG. 7A illustrates a cross sectional view of a partially formed heat spreader positioned within a stamping system, in accordance with embodiments of the present disclosure;

FIG. 7A;

FIG. 7B illustrates a cross sectional view of the partially formed heat spreader of FIG. 8A illustrates a cross sectional view of a partially formed heat spreader within a stamping system, in accordance with embodiments of the present disclosure;

FIG. 8B illustrates a cross sectional view of a fully formed heat spreader within the stamping system of FIG. 8A;

FIG. 8C illustrates a cross sectional view of a heat spreader after processing within stamping system of FIG. 8A;

FIG. 9A illustrates a top view of a die for use in a stamping system, in accordance with embodiments of the present disclosure; and

FIG. 9B illustrates a side elevation view of the die of FIG. 9A.

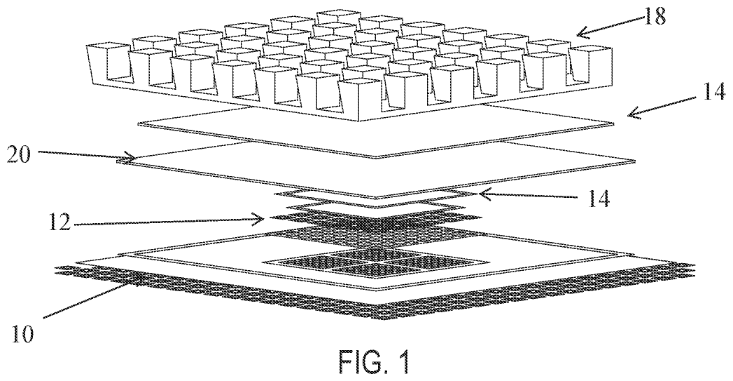

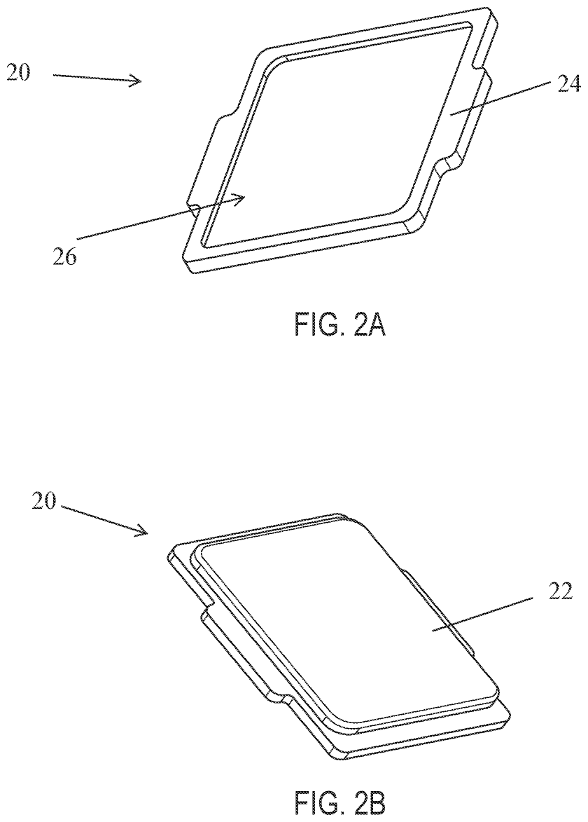

Corresponding reference characters indicate corresponding parts throughout the several views. Unless stated otherwise the drawings are drawn to scale and proportional.

### DETAILED DESCRIPTION

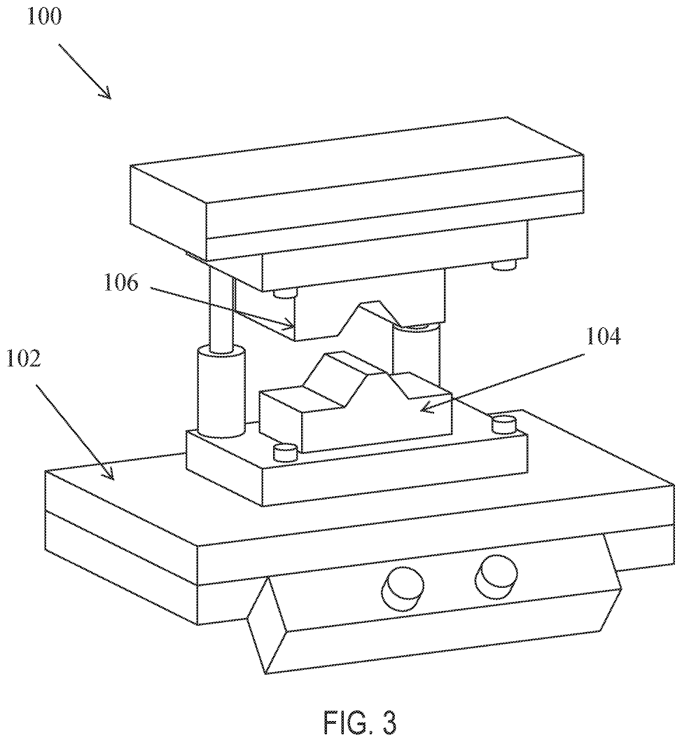

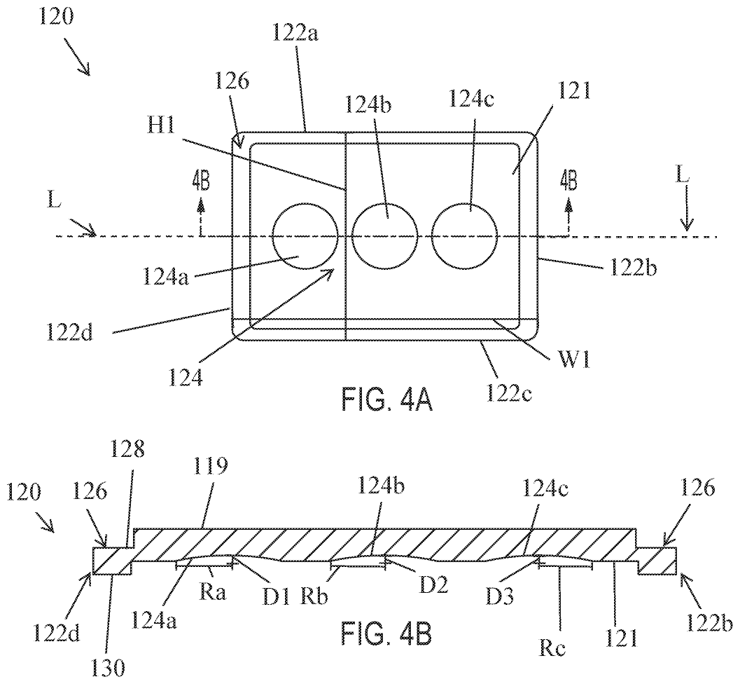

FIG. 3 schematically illustrates a stamping system 100 that may be used for forming a heat spreader, as will be described further with reference to FIGS. 4-9B. Specifically, stamping system 100 includes a plate 102 for securing a die 104 in place. Die 104 and plate 102 are secured such that during the stamping process die 104 and plate 102 remain stationary. Stamping system 100 further includes a punch 106 that is configured for repeated motion up and down in a vertical direction. In operation, a sheet of material, for example a metal, may be placed onto die 104 and punch 106 may be actuated by a ram for downward motion onto the material. During this process, the punch 106 is forced downwardly onto the material within stamping system 100 to press the material to conform to the shape of die 104 and/or punch 106. For example, as illustrated, die 104 has a protrusion that extends upward while punch 106 has a corresponding V-shaped groove. As a result of this, once compressed, the work piece between die 104 and punch 106 will have a projection matching the shape of the projection of die 104 and the groove of punch 106. While illustrated as having a projection, die 104 and/or punch 106 may have varying shapes and configurations. For example, die 104 and/or punch 106 may have a flat profile, domed profile, or otherwise irregularly shaped profile. Stamping system 100 may be used to form heat spreader 120, further described below, using a die 104 and punch 106 to perform one or more steps to cold-form a blank of material into the desired shape and configuration of heat spreader 120.

FIG. 4A illustrates a bottom view of an embodiment of a heat spreader 120 that may be formed from a stamping process, for example with stamping system 100 of FIG. 3, or a variation thereof. Heat spreader 120 defines a rectangular shape having a first side 122a, a second side 122b, a third side 122c and a fourth side 122d. A width W1 of heat spreader 120 is defined by distance between second side 122b and fourth side 122d while heat spreader 120 defines a height H1 defined by a distance between first side 122a and third side 122c. In some embodiments, width W1 is approximately equal to height H1 such that heat spreader 120 is defined by a square shape, while in the illustrated embodiment, width W1 is greater than height H1.

Heat spreader 120 additionally includes a central surface defining a plurality of domes 124 extending from a bottom surface 121 (FIG. 4B) of heat spreader 120. Illustratively, domes 124 extend inwardly into heat spreader 120, and as such are also referred to herein as cavities. Illustratively, plurality of cavities 124 includes a first cavity 124a, a second cavity 124b, and a third cavity 124c. Each of cavities 124 is generally circular in shape, however, various other shapes and/or configurations of cavities 124 may be incorporated. For example, cavities 124 may be generally rectangular, triangular, or otherwise irregular in shape. The ability to vary shape and amount of cavities 124 provides the advantage of increasing the amount of uses for heat spreader 120 as heat spreader 120 may be customized to work with a desired chip and/or processor. Additionally, as illustrated, plurality of cavities may be longitudinally aligned with a longitudinal axis L of heat spreader 120. However, in various other embodiments, the positioning of cavities 124 may be staggered or otherwise arrayed across the bottom surface 121 of the heat spreader 120.

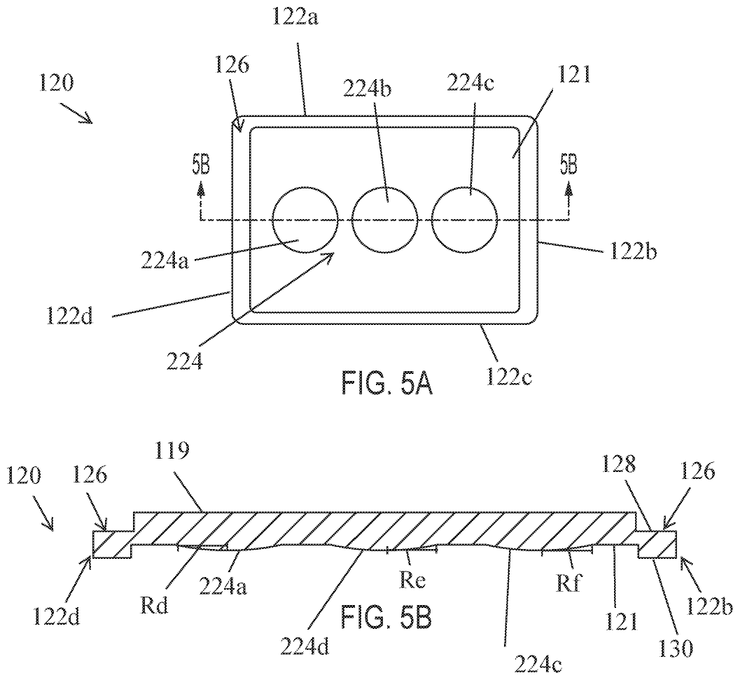

As illustrated in the cross sectional view of FIG. 4B, each of cavities 124 includes a radius, illustratively a lateral radius R. Illustratively, first cavity 124a includes a lateral radius Ra, second cavity 124b includes a lateral radius Rb, and third cavity 124c includes a radius Rc. In the illustrative embodiment of FIG. 4B, the values of each radius Ra, Rb, and Rc are generally equal to one another. The value of radii Ra-c may range from between approximately 5 mm to 15 mm. However, in other embodiments, values of each radius Ra-c may vary from one another. Further, lateral radius R may or not be equal to a maximum depth of each cavity 124. For example, as illustrated, each cavity 124 includes a depth D. Illustratively, first cavity 124a includes first depth D1, second cavity 124b includes second depth D2 and third cavity 124c includes third depth D3. While illustrated as each depth D having the same value as one another, in some embodiments, depth D of each individual cavity may be varied. In embodiments, the value of depths D1, D2, D3 may range from between approximately 0.005 mm to 0.03 mm. As depth D of each cavity 124 extends inwardly from bottom surface 121 into heat spreader 120, plurality of cavities 124 are classified as concave cavities 124. However, as will be described further herein with reference to FIGS. 5A-5B, the plurality of domes may have a convex configuration such that depth D measures the amount each cavity 124 protrudes downwardly from bottom surface 121.

With reference still to FIGS. 4A-4B, heat spreader 120 additionally includes an outer periphery 126 extending along each side 122 of heat spreader 120. Outer periphery 126 includes a top surface 128 and a bottom surface 130, wherein top surface 128 of outer periphery 126 is positioned at a lower vertical height than a vertical height of a top surface 119 of heat spreader 120. Similarly, bottom surface 130 of outer periphery 126 is positioned at a vertical height below a vertical height of bottom surface 121 of heat spreader 120. In other words, outer periphery 126 is positioned between and spaced from top and bottom surfaces 119, 121 of heat spreader 120.

FIGS. 5A-5B illustrate an additional embodiment of heat spreader 120. As illustrated in FIG. 5A, heat spreader 120 includes a plurality of cavities that may also be referred to herein as domes 224. In embodiments, plurality of domes 224 includes a first dome 224a, a second dome 224b and a third dome 224c. Domes 224 are illustrated as being generally circular in shape, however in various other embodiments the shape of domes 224 may be varied. For example, domes 224 may be generally rectangular, triangular, polygonal or otherwise irregular in shape. As shown in FIGS. 5A-5B, each of the plurality of domes 224 is defined by a radius R. Illustratively, first dome 224a is defined by a radius Rd, second dome 224b is defined by a radius Re, and third dome 224c is defined by a radius Rf. In various embodiments, each of radii Rd, Re, and Rf may be approximately equal while in various other embodiments, the value of each radius Rd, Re, and Rf may vary relative to one another. Additionally, the radii R of each dome 224 extends outward relative to bottom surface 121 of heat spreader 120, and as such, domes 224 may be classified as convex domes.

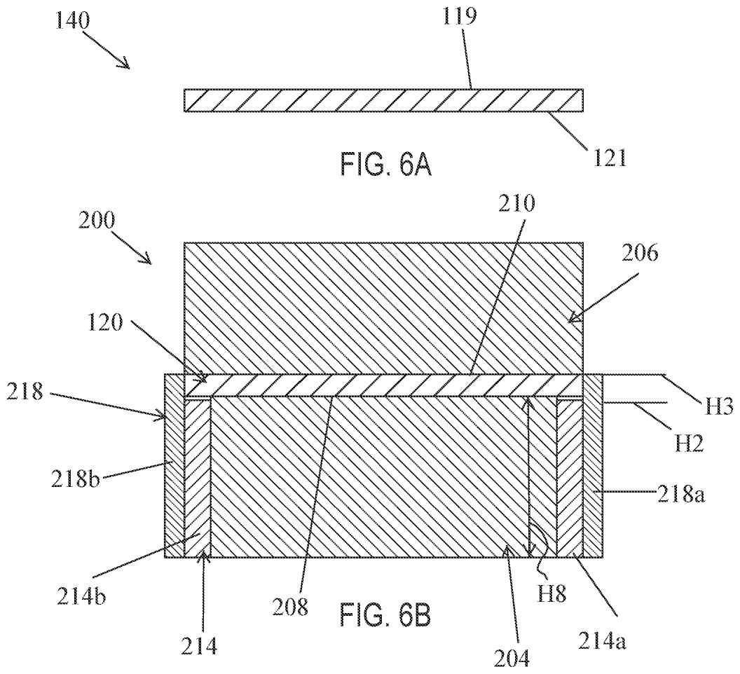

With reference to FIGS. 6A-9B, an exemplary method for forming the heat spreader 120 of FIGS. 4A-4B will be described. FIG. 6A illustrates a blank sheet 140 which may be formed of a metal, for example, copper. Blank sheet 140 may also be referred to herein as a work piece which may be cut or otherwise produced from a larger piece of sheet stock. Blank sheet 140 is inserted into stamping system 200 of FIG. 6B to undergo processing to reconfigure the blank work piece 140 into the desired shapes of the target heat spreader 120 (FIG. 4). As illustrated, stamping system 200 includes a die 204 and a punch 206, analogous to die 104 and punch 106 described and shown above with respect to FIG. 3. Die 204 and punch 206 are configured be actuated vertically into contact with blank sheet 140 to compress blank sheet 140 between die 204 and punch 206.

As illustrated, punch 206 includes a bottom surface 210 that has a flat and generally linear/planar profile. Bottom surface 210 fails to include any contours and is level across a width of bottom surface 210. Further, die 204 includes a top surface 208 that has a flat and linear/planar profile. Similar to bottom surface 210 of punch 206, top surface 208 of die 204 fails to include any contours and is substantially flat across a width of top surface 208. However, as will be described further herein, the shape profiles of top surface 208 and bottom surface 210 may be varied to achieve the desired embodiment of heat spreader 120. With reference still to FIG. 6B, stamping system 200 further includes a plurality of borders 214, illustratively a first border 214a and a second border 214b. Each border 214a, 214b is positioned on a side of die 204. In other words, die 204 is sandwiched between borders 214a, 214b. As illustrated, borders 214 extend to a vertical height H2 which may be less than a vertical height H8 of top surface 208 of die 204. Although two borders 214 are shown in the cross-section of FIG. 6B, it is understood that four borders 214 are provided to correspond to each of the four edges around the entire circumference of the workpiece 140.

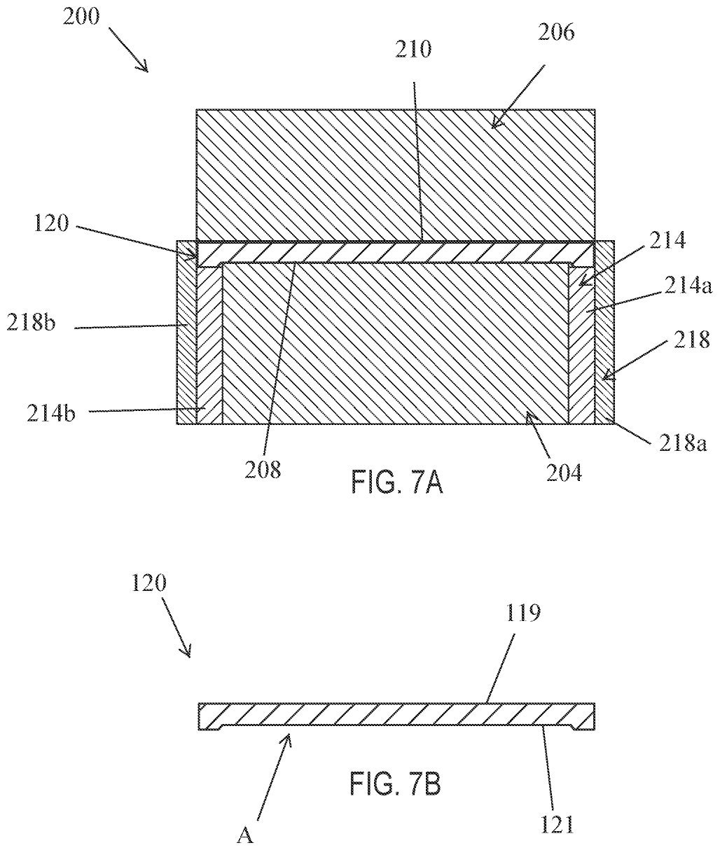

Further, stamping system 200 additionally includes plurality of outer walls 218, illustratively a first outer wall 218a and a second outer wall 218b, with additional outer walls 218 not shown but corresponding to the two additional borders described above. Each outer wall 218 is positioned adjacent a respective borders 214 and adjacent an entire thickness of heat spreader 120. In this way, stamping system 200 is configured as a closed tooling system, meaning that when material is pushed from blank sheet 140 and transferred outward, the material is contained within the outer walls 218 and is unable to extend laterally outward beyond outer walls 218. FIG. 7A illustrates blank sheet 140 positioned within stamping system 200 after punch 206 has been compressed onto blank sheet 140 and die 204.

FIG. 7B illustrates the resulting interim shape of the blank sheet 140 after processing by the die 204 and punch 206, also referred to as a partially formed embodiment of heat spreader 120. As such, FIG. 7B illustrates a partially complete embodiment of heat spreader 120 wherein a central surface A has been formed with punch 206 and die 204. The material displaced from central surface A has been pushed outward from central surface A towards sides of blank sheet 140. As a result of outer borders 218 being positioned at vertical height H3 which is higher than a vertical height H8 of die 204, the stamping process of FIG. 6A, which is also shown in FIG. 7B, begins to create outer periphery 126 (FIG. 4) of heat spreader 120. More specifically, material at an outer edge of heat spreader 120 is illustrated as extending vertically downward relative to central surface A. Partially formed heat spreader 120 of FIG. 7B is then inserted into an additional stamping system 300, a further variation of stamping system 100 (FIG. 3) to undergo an additional processing step.

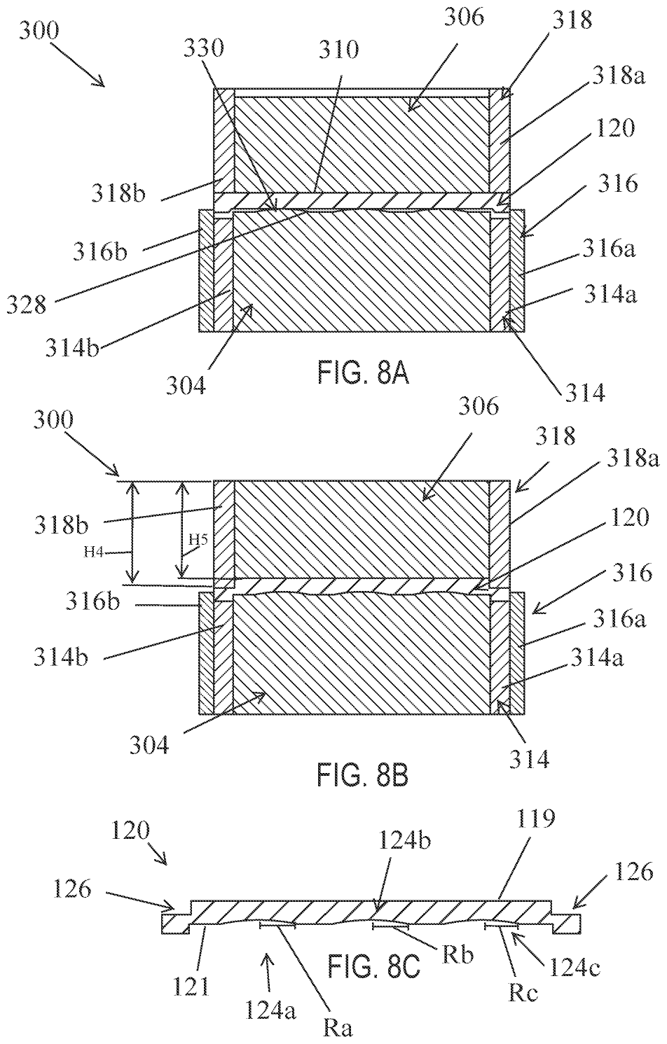

FIG. 8A illustrates the partially formed heat spreader 120 of FIG. 7B inserted within stamping system 300 prior to additional compression of blank sheet 140 within stamping system 300. As illustrated, stamping system 300 includes a die 304, a punch 306, a plurality of borders 314 positioned on either side of die 304, and a plurality of outer walls 316 positioned adjacent borders 314. Further, stamping system 300 includes a plurality of upper walls 318, illustratively a first upper wall 318a and a second upper wall 318b, it being understood that two additional upper walls 318 are included to form a rectangular arrangement. Upper walls 318 are positioned around punch 306 such that punch 306 is laterally “sandwiched” or enclosed between and within upper walls 318. In FIG. 8A, upper walls 318 are illustrated as extending to a vertical height H4 that may be greater than a vertical height H5 of punch 306. In this way, when punch 306 and upper walls 318 are actuated downwards to compress the partially formed heat spreader 120, upper walls 318 may extend to a vertical position below a vertical position of punch 306, as will be described further with reference to FIG. 8B.

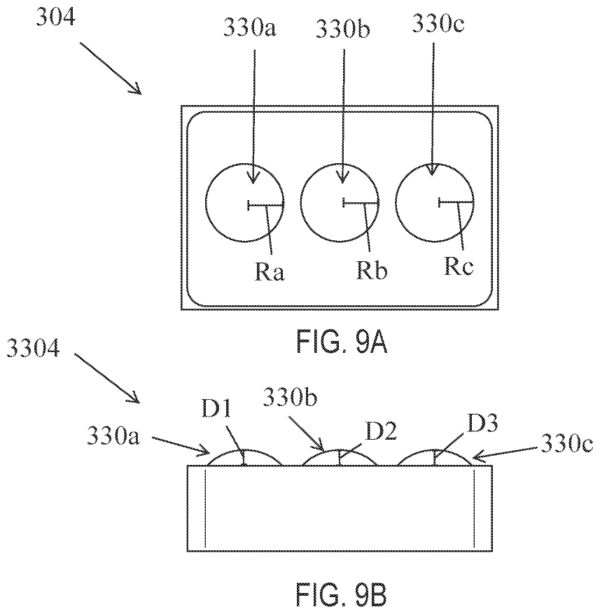

As illustrated in FIG. 8A, die 304 includes a top surface 328 including a plurality of protrusions 330. In embodiments, the plurality of protrusions 330 includes a first protrusion 330a, a second protrusions 330b and a third protrusion 330c. In embodiments, protrusions 330 are each domes extending from top surface 328 of die 304. In this embodiment, punch 306 includes a bottom surface 310 have a generally flat profile across bottom surface 310. In this way, when punch 306 is brought into contact with heat spreader 120 to compress the material into die 304, the material on top surface 119 (FIG. 7B) of partially complete heat spreader 120 is held in place and constrained to a substantially constant geometry, while protrusions 330 are compressed into bottom surface 121 (FIG. 7B) of heat spreader 120. The plurality of protrusions 330 push into the material and transfer material from bottom surface 121 of heat spreader 120 laterally outwards relative to each of plurality of protrusions 330. As such, material flows generally outward, as illustrated in FIG. 8C to form concave cavities 124 within bottom surface 121 of heat spreader 120. In these embodiments, protrusions 330 may each include a lateral radius and a depth that corresponds to resultant lateral radii Ra, Rb, Rc and depths D1, D2, D3 of cavities 124 (FIG. 4), as will be described further with reference to FIGS. 9A-9B.

Specifically, with reference to FIGS. 9A-9B, die 304 of stamping system 300 is illustrated. Each protrusion 330 may have a lateral radius R and a depth D. In the illustrative embodiment, first protrusion 330a is defined by lateral radius Ra and depth D1, second protrusion 330b is defined by lateral radius Rb and depth D2, and third protrusion 330c is defined by lateral radius Rc and depth D3. However, variations in the lateral radii and depths of protrusions 330 may be incorporated. Further, various other shapes, sizes and/or configurations of protrusions 330a-c may be incorporated based on the intended target configuration of the heat spreader. For example, in order to form domes 224 as shown in FIGS. 5A-5B, protrusions 330 may instead be cavities that extend inwardly from top surface 328 of die 304 the above described stamping process creates convex domes 224.

With reference again to FIGS. 8A-8C, and as previously disclosed, as punch 306 is actuated downward, upper walls 318 may extend further downward than punch 306. As such, material may flow outward and be compressed between borders 314 and upper walls 318. This compression forms outer periphery 126 of heat spreader 120 which is spaced from remainder of heat spreader 120 and extends around entirely of heat spreader 120 such outer periphery extends around at least a portion of each cavity 124. While the above method was described for forming heat spreader 120 having cavities 124 as shown in FIG. 4A, the method and configurations of stamping systems 100, 200 may be varied to result in a varied configuration of heat spreader 120 and/or cavities, and the above described configurations were provided merely for example.

Aspects

Aspect 1 is a heat spreader having a longitudinal axis and including a top surface opposite a bottom surface, a plurality domes formed within and extending from the bottom surface, wherein each dome of the plurality of domes is defined by a radius and a depth, and wherein the plurality of domes are longitudinally aligned with one another along the longitudinal axis.

Aspect 2 is the heat spreader of Aspect 1, wherein each of the plurality of domes is defined by a curved profile.

Aspect 3 is the heat spreader of Aspect 1 or Aspect 3, wherein the plurality of domes is defined by a first dome, a second dome, and a third dome.

Aspect 4 is the heat spreader of any of Aspects 1-3, wherein the plurality of domes each extend upwardly relative to the bottom surface of the heat spreader, such that each dome forms a cavity within the heat spreader.

Aspect 5 is the heat spreader of any of Aspects 1-3, wherein the plurality of domes each extend downwardly relative to the bottom surface of the heat spreader.

Aspect 6 is the heat spreader of any of Aspects 1-5 wherein the radius of each of the plurality of domes is between approximately 5 mm and 15 mm.

Aspect 7 is the heat spreader of any of Aspects 1-6, wherein the depth of each of the plurality of domes is between approximately 0.005 mm and 0.03 mm.

Aspect 8 is the heat spreader of any of Aspects 1-7, wherein the heat spreader is defined by a generally rectangular shape defined by at least four sides.

Aspect 9 is the heat spreader of Aspect 8, wherein the heat spreader includes an outer periphery that extends along each of the four sides of the heat spreader.

Aspect 10 is the heat spreader of Aspect 9, wherein the outer periphery is at least partially vertically offset from the bottom surface of the heat spreader.

Aspect 11 is the heat spreader of any of Aspects 1-10, wherein the heat spreader is composed of copper.

Aspect 12 is a heat spreader including a top surface opposite a bottom surface, a first cavity within and extending upwardly from the bottom surface, the first cavity defined by a lateral radius and a depth, a second cavity within and extending upwardly from the bottom surface and positioned adjacent the first cavity, the second cavity defined by a lateral radius and a depth, and a third cavity within and extending upwardly from the bottom surface and positioned adjacent the second cavity, the third cavity defined by a lateral radius and a depth. The heat spreader further includes wherein the first, second and third cavities are defined by a generally domed profile.

Aspect 13 is the heat spreader of Aspect 12 wherein the lateral radius of the first cavity, second cavity, and third cavity is between approximately 5 mm and 15 mm.

Aspect 14 is the heat spreader of Aspect 12 or Aspect 13, wherein the depth of each first, second, and third cavity is between approximately 0.005 mm and 0.03 mm.

Aspect 15 is a method of forming a heat spreader including a method of forming a heat spreader including stamping a central surface of a sheet of material with a die and a press of a stamping system to transfer material outward form a central surface, constrained the material of atop surface of the sheet of material in a substantially constant geometry, and during the step of constraining, stamping a plurality of domes into a bottom surface of the sheet of material with a second die and a second press of a second stamping system to create a heat spreader.

Aspect 16 is the method of Aspect 15, wherein the die of the second stamping system includes a plurality of protrusions extending from a top surface of the die.

Aspect 17 is the method of Aspect 15 or Aspect 16, wherein during the step of stamping the plurality of domes into the sheet of metal to form the heat spreader, material flows laterally outward to form an outer periphery of the heat spreader.

Aspect 18 is the method of any of Aspects 15-17, wherein the plurality of domes includes at least three domes and the plurality of protrusions of the die includes at least three protrusions.

Aspect 19 is the method of any of Aspects 15-18, wherein the plurality of domes extend inwardly relative to the bottom surface of the heat spreader, such that the plurality of domes define a plurality of cavities.

Aspect 20 is the method of any of Aspects 15-18, wherein the plurality of domes extend downwardly relative to the bottom surface of the heat spreader.

While this invention has been described as having exemplary designs, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

1. A heat spreader having a longitudinal axis, comprising:
a top surface opposite a bottom surface;
a plurality of domes formed within and extending from the bottom surface, wherein each dome of the plurality of domes is defined by a radius and a depth; and
wherein the plurality of domes are longitudinally aligned with one another along the longitudinal axis.

2. The heat spreader of claim 1, wherein each of the plurality of domes is defined by a curved profile.

3. The heat spreader of claim 1, wherein the plurality domes is defined by a first dome, a second dome and a third dome.

4. The heat spreader of claim 1, wherein the plurality of domes each extend upwardly relative to the bottom surface of the heat spreader, such that each dome forms a cavity within the heat spreader.

5. The heat spreader of claim 1, wherein the plurality of domes each extend downwardly relative to the bottom surface of the heat spreader.

6. The heat spreader of claim 1, wherein the radius of each of the plurality of domes is between approximately 5 mm and 15 mm.

7. The heat spreader of claim 1, wherein the depth of each of the plurality of domes is between approximately 0.005 mm and 0.03 mm.

8. The heat spreader of claim 1, wherein the heat spreader is defined by a generally rectangular shape defined by at least four sides.

9. The heat spreader of claim 8, wherein the heat spreader includes an outer periphery that extends along each of the four sides of the heat spreader.

10. The heat spreader of claim 9, wherein the outer periphery is at least partially vertically offset from the bottom surface of the heat spreader.

11. The heat spreader of claim 1, wherein the heat spreader is composed of copper.

12. A heat spreader, comprising:
a top surface opposite a bottom surface;
a first cavity within and extending upwardly from the bottom surface, the first cavity defined by a lateral radius and a depth;
a second cavity within and extending upwardly from the bottom surface and positioned adjacent the first cavity, the second cavity defined by a lateral radius and a depth;
a third cavity within and extending upwardly from the bottom surface and positioned adjacent the second cavity, the third cavity defined by a lateral radius and a depth;
wherein the first, second and third cavities are defined by a generally domed profile.

13. The heat spreader of claim 12, wherein the lateral radius of the first cavity, second cavity, and third cavity is between approximately 5 mm and 15 mm.

14. The heat spreader of claim 12, wherein the depth of each first, second and third cavity is between approximately 0.005 mm and 0.05 mm.

15. A method of forming a heat spreader, the method comprising:
stamping a central surface of a sheet of material with a die and a press of a stamping system to transfer material outward from a central surface;
constrained the material of a top surface of the sheet of material in a substantially constant geometry; and
during the step of constraining, stamping a plurality of domes into a bottom surface of the sheet of material with a second die and a second press of a second stamping system to create a heat spreader.

16. The method of claim 15, wherein the die of the second stamping system includes a plurality of protrusions extending from a top surface of the die.

17. The method of claim 15, wherein during the step of stamping the plurality of domes into the sheet of metal to form the heat spreader, material flows laterally outward to form an outer periphery of the heat spreader.

18. The method of claim 15, wherein the plurality of domes includes at least three domes and the plurality of protrusions of the die includes at least three protrusions.

19. The method of claim 15, wherein the plurality of domes extend inwardly relative to the bottom surface of the heat spreader, such that the plurality of domes define a plurality of cavities.

20. The method of claim 15, wherein the plurality of domes extend downwardly relative to the bottom surface of the heat spreader.
